(19) United States
(12) Patent Application Publication
(10) Pub. No.: US 2005/0280475 A1
(43) Pub. Date: Dec. 22, 2005

(54) Charge pump of a phase locked loop with switchable system bandwidth and method for controlling such a charge pump

(75) Inventor: Andreas Hanselmann, Schwabisch Hall (DE)

Correspondence Address: BIRCH STEWART KOLASCH & BIRCH, PO BOX 747, FALLS CHURCH, VA, 22040-0747, US

(73) Assignee: ATMEL GERMANY GMBH

(21) Appl. No.: 11/156,716

(22) Filed: Jun. 21, 2005

(30) Foreign Application Priority Data
Jun. 21, 2004 (DE) 10 2004 031 913.8

(51) Int. Cl. H03L 7/00

(52) U.S. Cl. 331/16

(57) ABSTRACT

A charge pump of a phase locked loop and method thereof, includes a first current source that supplies a first additive partial current to a node, a first current sink that draws a first subtractive partial current from the node, a second current source that supplies a second additive partial current to a node, and a second current sink that draws a second subtractive partial current from the node, wherein a sum of the currents (I_{—}2+, I_{—}1−) provides a charge current for a loop filter of the phase locked loop and a sum of the currents (I_{—}1+, I_{—}2−) provides a discharge current for the loop filter. The charge pump also includes a first current control element and a second current control element. The first current control element controls the sum of the first additive partial current (I_{—}1+) and the second subtractive partial current (I_{—}2−), and the second current control element controls the sum of the first subtractive partial current (I_{—}1−) and the second additive partial current (I_{—}2+).

This nonprovisional application claims priority under 35 U.S.C. § 119(a) on German Patent Application No. 102004031913.8, which was filed in Germany on Jun. 21, 2004, and which is herein incorporated by reference.

### BACKGROUND OF THE INVENTION

1. Field of the Invention

The present invention relates to a charge pump of a phase locked loop, having a first current source that supplies a first additive partial current to a node, and having a first current sink that draws a first subtractive partial current from the node, having a second current source that supplies a second additive partial current to a node, and having a second current sink that draws a second subtractive partial current from the node. The invention further relates to a method for controlling the charge pump of the phase locked loop.

2. Description of the Background Art

A charge pump of this nature, which is also known as a “differential charge pump,” and a method of this nature, are known from U.S. Pat. No. 6,011,822.

To aid in understanding the invention, the following first describes the function of a phase locked loop qualitatively. A phase locked loop generally has a voltage controlled oscillator (VCO), which provides an AC voltage. The frequency of the AC voltage is a function of a DC control voltage that is provided to the VCO by a loop filter that has capacitive elements. In this environment, charge pumps serve to provide pulsed charge currents and discharge currents for the loop filter.

To implement a closed phase locked loop, the frequency of the VCO's AC voltage is divided down to the level of a reference frequency, which is provided by a quartz oscillator for example, by a frequency divider with division factor N. A phase/frequency detector (PFD) compares the divided-down VCO frequency with the reference frequency. Depending on the result of the comparison, the PFD outputs a charge pulse (UP pulse) when the phase of the reference signal is leading, and outputs a discharge pulse (DOWN pulse) when the phase of the divided VCO signal is leading. Charge pulse and discharge pulse are controlled by flip-flop switches that are reset at the moment when both switches are on. The resetting of the flip-flop switches is delayed so that when phase equality exists, charge and discharge pulses arise which cancel one another out.

Both the charge pulses and the discharge pulses are smoothed by the loop filter, so that the DC control voltage output to the VCO by the loop filter is raised by charge current pulses (UP pulses) and is lowered by discharge current pulses (DOWN pulses). Overall, when the VCO frequency is too low the charge current pulses predominate, so that the DC control voltage rises and the VCO responds with a frequency increase. Similarly, when the VCO frequency is too high the discharge current pulses predominate, so that the control voltage drops, to which the VCO responds with a frequency decrease.

In this connection, U.S. Pat. No. 6,011,822 deals with so-called static phase errors, which arise in real phase locked loops in the steady state from unavoidable differences in the current sources, from differing switching times of the current sources and sinks, from undesirable charge injection by participating switches in the charge pump, and from inadequate measures to compensate for these effects. According to U.S. Pat. No. 6,011,822 these undesirable effects are resolved by a differential charge pump, hence a charge pump in which a current source and a current sink work against one another.

In addition to the various static phase errors dealt with in U.S. Pat. No. 6,011,822 for different control voltages of the VCO, however, phase errors that vary with current level also arise in phase locked loops having switchable bandwidths that are controlled through the charge current of the charge pump. The VCO frequency is changed by a change in the DC control voltage (tuning voltage), with a change in this voltage being accomplished through charge transfer in capacitive elements in the loop filter. Depending on whether charge transfer is to take place quickly, hence with wide loop bandwidth, or slowly, hence with a narrow loop bandwidth, the charge pump must output currents of different levels. If the VCO frequency is changed by changing the division factor N in the loop, the loop bandwidth is increased by switching on a high charge current of the charge pump. As a desired result, the capacitive elements located in the loop filter experience rapid charge transfer, so that the VCO rapidly reaches its target frequency. Since the loop bandwidth in this case is very wide, the noise present in the loop modulates the output frequency of the VCO, which is not desired. In order to minimize this noise and thus achieve a clean carrier signal (output frequency of the VCO), after the target frequency is reached in a settling process with high bandwidth, the loop bandwidth of the system is decreased by a reduction in the level of the current of the charge pump and/or discharge pump.

Moreover, in an ideal charge pump the UP and DOWN pulses cancel one another out in the steady state. In real charge pumps, however, leakage currents, asymmetries and production variations in the components used result in a phase offset between the signal of the reference frequency source and the signal of the 1/N divider. This phase offset differs for different current levels of the charge pump; with switching of the loop bandwidth via the current level in the steady state, this results in a control action that corrects the phase error that arises. This offset is settled out with the narrow bandwidth of the phase locked loop, which takes a relatively long time. The time savings achieved by widening the system bandwidth is eliminated by the slow phase readjustment occurring after switching of the loop bandwidth.

As has already been mentioned, the DC control voltage for the VCO depends on the charge state of the capacitive elements in the loop filter. In order to rapidly establish an altered VCO frequency, a rapid charge transfer in the capacitive elements is thus desirable, something which can be achieved through relatively high current levels for the charging and discharging, for example. On the other hand, the loop bandwidth is increased by the high current level in the charge pump, and thus a large amount of noise is modulated onto the VCO.

### SUMMARY OF THE INVENTION

It is therefore an object of the present invention to provide a charge pump for a phase locked loop and a method for controlling a charge pump, making possible rapid settling of the phase locked loop at a frequency change through both high current levels and thus wide loop bandwidth, and through small differences in the phase offset when changing between low and high current levels of the charge pump, in order to be able to switch the bandwidth of the phase locked loop without an additional control action. In addition, a dead time for very low current levels of the charge pump is to be avoided.

This object is attained in a charge pump of the aforementioned type by a first current control element and a second current control element, with the first current control element controlling a combined action of a first subset of the current sources and current sinks and the second current control element controlling a second subset of the current sources and current sinks that is complementary to the first subset, such that lower effective charge and discharge current levels are produced in a first control state than in a second control state.

In addition, this object is attained in a method of the aforementioned type in that a combined action of a first subset of the current sources and current sinks is controlled by a first current control element, and a second subset of the current sources and current sinks that is complementary to the first subset is controlled by a second current control element such that lower effective current levels of the charge pump result in a first control state than in a second control state.

The object of the invention is attained in full through these features. Through this variation of the combined action of the current sources and current sinks with the aid of current control elements, the charge pump can be operated with a high effective current level during a settling process, and with a low effective current level in the steady state, without encountering differences between the two states in properties of the current sources and current sinks which depend on the individual current flow through the current sources and current sinks. The elimination in accordance with the invention of the change in these current-dependent properties efficaciously avoids possible phase differences between the steady state with low current level and the settling process with high current level.

In accordance with the invention, independent of the effective current level delivered by the charge pump, the various elements of the charge pump pass current levels that are uniform for each individual element. Thus the relationships at individual current sources/current sinks of the charge pump change only insignificantly. The phase error (phase offset) thus remains constant, independent of the effective current level at the output of the charge pump. Parasitic capacitances such as base capacitances and space-charge regions of semiconductor elements used in current sources and/or current sinks each undergo rapid charge transfer, so that sharp defined pulses are always produced. Even in the steady state (narrow residual pulse) and low effective current level at the output of the charge pump, no dead time occurs. Thus, in addition, the residual pulse width that is generated by the delayed resetting of the flip-flop switch in the PFD can be kept small even for the case of small current levels of the charge pump. The narrow residual pulse of the CP also reduces the occurrence of (spurious) interference lines, which can appear at spacings of the reference signal and multiples thereof from the VCO output signal, especially in the case of a high current level of the charge pump.

With regard to the embodiments of the charge pump, it is preferred that the first subset includes the first and the second current source and that the complementary second subset includes the first current sink and the second current sink, with an effective charge current resulting from the sum of the contributions from the first and second current sources, and with an effective discharge current resulting from the sum of the contributions from the first and second current sinks.

This embodiment can correspond to a parallel connection of two charge pumps, whereby one of which can be switched in or out as needed.

It is also preferred that, for example, a contribution of the second current source and a contribution of the second current sink to the effective current level of the charge pump in the first control state, is at least smaller than in the second control state.

In this embodiment, the second current source and the second current sink can operate alone in the low-current case, and in the high-current case adequately large currents for a rapid frequency change can be switched in temporarily through the first current source and the first current sink.

As an alternative to the aforementioned creation of the subsets, it is preferred for the first subset to include the second current source and the first current sink, and for the complementary second subset to include the second current sink and the first current source.

In this embodiment, the current sources and current sinks are to a certain extent cross-connected to one another so that the low-current case can be implemented by subtraction of currents and the high-current case can be implemented by switching out the contributions to be subtracted.

It is also preferred for the first current control element to influence the first additive partial current that the first current source supplies to the node, and for the second current control element to influence the first subtractive partial current that the second current sink draws from the node.

Through this embodiment, the properties and in particular the operating points of the current sources and current sinks are not changed at a switchover between two effective current levels of the charge pump. The effective charge current is varied by varying the current flowing out of a node, and the effective discharge current is varied by varying the charge current flowing to the node.

Further, the first current control element can digitally switch the first additive partial current on or off, and the second current control element can digitally switch the first subtractive partial current on or off. In this regard the concept of digital switch-on or switch-off refers to the complete switching in or switching out of the first additive and first subtractive partial current.

Such a digital switch-on or switch-off results in a high reproducibility of the conditions in both switching states with low effort, for example in comparison to a continuous reversal of current levels. It is a matter of course, however, that the invention also permits continuous reversal processes outside of this embodiment.

In addition, the first current source can supply a current level such as is drawn by the first current sink, and the second current sink can draw a current level such as is supplied by the second current source.

Analogously, the current levels of the second current source and the second current sink can be substantially equal in magnitude (with different arithmetic signs).

Due to this embodiment with symmetrical charge and discharge currents, the charge transfer in a loop filter capacitor can be determined by the difference of the time integrals over charge and discharge current pulses associated with one another, and is thus perfectly adapted to the behavior of the output signals of a preceding phase/frequency detector. The difference in the time integrals over the charge current pulses and the discharge current pulses determines the change in the DC control voltage output by the loop filter to the VCO and thus the output frequency of the VCO.

The current level supplied by the first current source can be smaller than the current level drawn by the second current sink.

Due to this embodiment, an effective discharge current is always provided for the design that implements the low-current case by subtraction. The effective value of this discharge current can be varied by controlling or switching the current level supplied by the first current source. In the extreme case, the first current source and the first current sink are switched in fully in the stationary state and are switched out fully for rapid settling in the extreme case. Thus, in total a high charge and discharge current level is achieved for settling, the level being determined by the second current source and second current sink alone, while the smaller discharge current level for the stationary state is established as the difference of the second subtractive partial current and the first additive partial current, and the smaller charge current level is established as the difference of the first subtractive partial current and the second additive partial current. In general, the level of the first additive and first subtractive partial current will be a function of the desired bandwidth and of the stability of the system.

The charge pump can include a control unit that actuates the first current control element and the second current control element in parallel.

Since the first current control element influences the discharge current sum and the second current control element influences the charge current sum, the parallel actuation of both current control elements, and thus the parallel control of an additional source and an additional sink, achieves a synchronous effect on the node, leading to a synchronous change in the sum currents at the node. Since the effective charge current pulse and the effective discharge current pulse are each created at the node, this design permits synchronous switchover between high charge and discharge currents on the one hand and low charge and discharge currents on the other hand.

With regard to embodiments of the method, a sum of the currents of the second current source and the first current sink can provide a charge current for a loop filter of the phase locked loop and a sum of the currents of the second current sink and the first current source can provide a discharge current for the loop filter, wherein the discharge current is varied by the first current control element and wherein the charge current is varied by the second current control element.

Also, the sum of the currents can be increased for a settling process at a changed frequency of the phase locked loop and can be decreased in a stationary state of the phase locked loop.

Due to this embodiment, a rapid settling in the event of a frequency change is achieved together with a low noise component in the VCO signal in stationary states.

In this context, the first current control element and the second current control element can be operated in parallel.

Furthermore the first subtractive partial current can be digitally switched on or off and the second additive partial current can be digitally switched on or off.

These embodiments of the process produce the advantages of the corresponding embodiments of the charge pump.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a phase locked loop;

FIG. 2 illustrates the function of a phase/frequency detector, which supplies an input signal for the charge pump;

FIG. 3 are timing diagrams of input signals and output signals of the phase/frequency detector from FIG. 2;

FIG. 4 illustrates a first example embodiment of a charge pump according to the invention;

FIGS. 5a-b show plots over time of a control signal that controls the charge pump at the transition from a first frequency to a second frequency;

FIGS. 6a-b show plots of loop gain over frequency as a function of the switching state of the example embodiment from FIG. 4; and

FIG. 7 illustrates a second example embodiment of a charge pump according to the invention.

### DETAILED DESCRIPTION

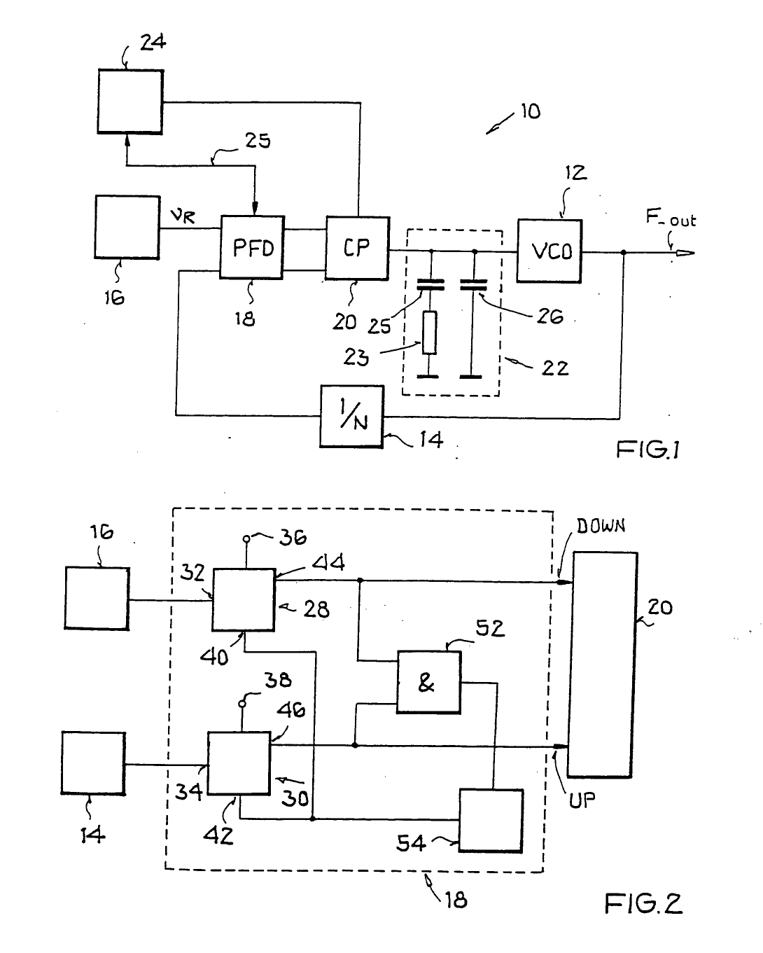

FIG. 1 shows a phase locked loop 10 having a VCO 12, a frequency divider 14, a reference frequency source 16, a phase/frequency detector PFD 18, a charge pump 20 (charge pump CP), a loop filter 22 and a control unit 24. The VCO 12 contains, for example, an LC resonant circuit with an inductance L and a capacitance C, the value of which is a function of a DC control voltage. Inductance and controllable capacitance determine the oscillation frequency and thus the frequency F_out of the VCO. The VCO frequency divided down by the 1/N divider 14 is fed to the phase/frequency detector 18 together with a reference frequency output by the reference frequency source 16. The phase/frequency detector uses “UP” and “DOWN” pulses to control the charge pump 20, which supplies the loop filter 22 with corresponding charge current pulses and discharge current pulses. The loop filter 22 has at least one capacitive element 25, 26, whose total charge Q is determined by the charge and discharge current pulses, wherein the total charge Q, together with the value of the loop filter capacitance, determines the value of the control voltage U for the VCO 12. In addition, the loop filter optionally has a resistor 23 that is switched in the event of a large bandwidth difference, and thus contributes to stable behavior of the loop. The control unit 24 uses a control signal I_CP_SW to control the charge pump 22 in a manner described in detail below. In this context the I_CP_CW signal is preferably synchronized with the reference signal and/or the divided VCO signal through the connection 25 so that a control intervention does not take place with active UP or DOWN pulses.

FIG. 2 shows details of the phase/frequency detector 18. The phase/frequency detector 18 has two flip-flop switches 28, 30, each of which has a control input 32, 34, a supply voltage connection 36, 38, a reset connection 40, 42, and an output 44, 46. The signal 48 from the reference transmitter 16 shown in FIG. 3 is present at the control input 32 of the first flip-flop 28. Similarly, the signal 50 from the 1/N divider 14, which is likewise shown in FIG. 3, is present at the control input 34 of the second flip-flop 30. In the case shown, the phase locked loop 10 is in the steady state and the frequency and phase of the signals 48, 50 are equal. For reasons of clarity, no phase offset is shown. Rising edges in each of the signals 48, 50 set signals at the outputs 44, 46 of the flip-flops 28, 30, while the output 44 triggers a discharge current pulse “DOWN” and the output 46 triggers a charge current pulse “UP,” such as are shown in FIG. 3.

In addition, both outputs 44, 46 are connected to an AND gate 52, which resets the flip-flops 28, 30 through a delay element 54 when a minimum pulse width delta_t has elapsed. As a result, the phase/frequency detector 18 produces symmetrical “UP,” “DOWN” pulses with which the charge pump 20 is driven.

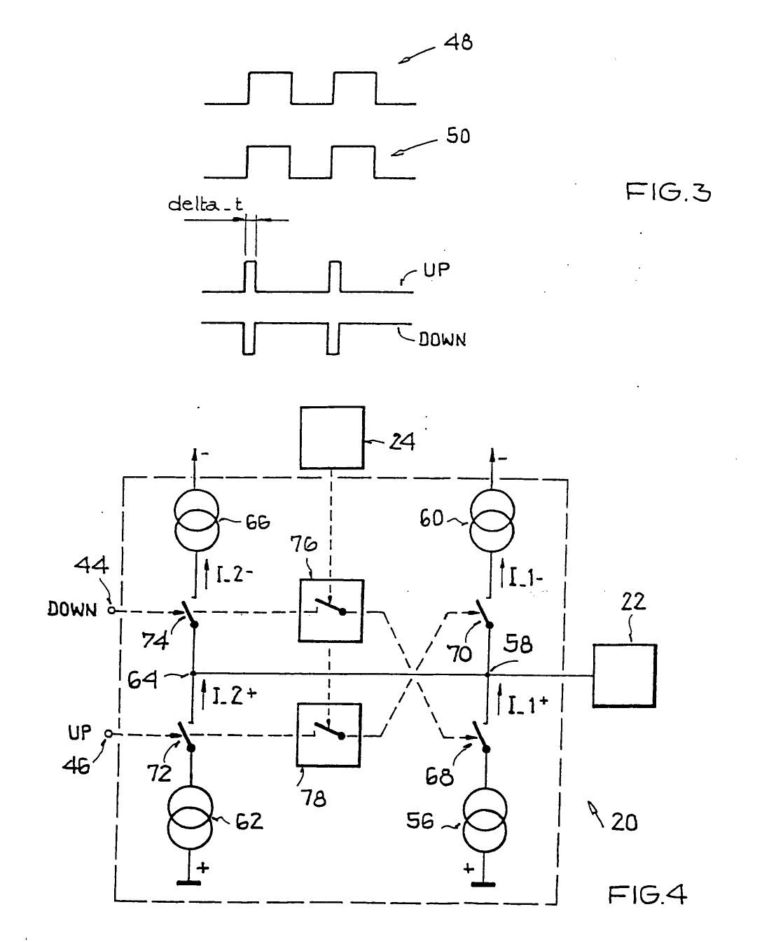

FIG. 4 shows a first example embodiment of an inventive charge pump 20 with a first current source 56 that supplies a first additive partial current I_1+ to a first node 58, and with a first current sink 60 that draws a first subtractive partial current I_1− from the first node 58, and with a second current source 62 that supplies a second additive partial current I_2+ to a second node 64, and with a second current sink 66 that draws a second subtractive partial current I_2− from the second node 64, wherein a sum of the currents I_2+ and I_1− provides a charge current for the loop filter 22 of the phase locked loop 10 and a sum of the currents I_1+, I_2− provides a discharge current for the loop filter 22. The first node 58 may be identical to the second node 64.

This embodiment corresponds to the aforementioned cross-connection of the current sources 56, 62 and current sinks 60, 66. In addition, the embodiment shown in FIG. 4 has an I_1+ switch 68, an I_1− switch 70, an I_2+ switch 72, an I_2− switch 74, a first current control element 76, and a second current control element 78. The two current control elements 76, 78 are controlled by the control unit 24 of the phase locked loop 10. In the example embodiment shown in FIG. 4, the current control elements 76, 78 are represented as open switches. In this switch state, only the switches 72 and 74 are actuated by UP and DOWN pulses, respectively, while the switches 68 and 70 are not. The switches 68 and 70 are continuously open in this switch state of the current control elements 76, 78, corresponding to the high-current case. For the low-current case, in contrast, the current control elements are controlled or switched to conduct, so that also the switches 68 and 70 are actuated by DOWN and UP pulses, respectively.

The current sources 56 and 62, and also the current sinks 60 and 66, are preferably dimensioned such that the first current source 56 supplies the same current level I_1+ to the first node 58 that the first current sink 60 draws from the first node 58 as current level I_1−. Thus, with reference to the first node 58, in this preferred embodiment I_1+=minus I_1−, where the value of I_1+=4.5 mA, in one example. Similarly, the second current source 62 and the second current sink 66 are preferably dimensioned such that I_2+=minus I_2−, where the value of I_2+ in the example is 5 mA. In general, the current sources and current sinks are dimensioned in the scope of this embodiment such that the current levels with index 1 are smaller than the current levels with index 2.

We shall first examine the low-current case with current control elements 76, 78 controlled to conduct. In this example, when an UP pulse occurs the second current source 62 supplies, for example, 5 mA to node 64 and the first current sink 60 draws 4.5 mA from node 58. In this low-current case with these current levels, the difference 5 mA−4.5 mA=0.5 mA is effectively supplied to the loop filter 22 as the charge current level. Similarly, the capacitors of the loop filter 22 are effectively discharged at 0.5 mA in the event of a down pulse in the low-current case.

In the high-current case, which in the embodiment shown in FIG. 4 corresponds to the switching state with open current control elements shown, both the first current source 56 and the first current sink 60 are separated from the node 58, since the switches 68, 70 are continuously open in the absence of control by DOWN pulses or UP pulses. In this case, the effective current level with which the loop filter is charged or discharged is comprised solely of contributions from the second current source 62 and the second current sink 66, corresponding to effective values of +/−5 mA with the specific example values cited.

For a settling process, the control unit 24 actuates the current control elements 76, 78 such that the phase locked loop 10 settles at a new frequency with high bandwidth and thus with high charge current of the charge pump 20, which is to say works with the first current source 56 switched off and the first current sink 60 switched off. In this process, the I_CP_CW signal is preferably synchronized with the reference signal and/or the divided VCO signal such that the switchover does not take place with active UP or DOWN pulses. The current level is then determined solely by the current of the second current source 62 and the second current sink 66. Once the target frequency set by the division factor N has been reached and the capacitive elements in the loop filter 22 have undergone charge transfer, the bandwidth of the loop is reduced by switching in the first current source 56 and the first current sink 60, which are then controlled by the same UP and DOWN signals from the phase frequency detector 18 as the second current source 62 and the second current sink 66. The control itself is crossed over, however, which is to say that on an UP pulse I_2+ and I_1− are simultaneously switched on, and on a DOWN pulse I_2− and I_1+ are simultaneously switched on. Thus, when the first current source 56 and the first current sink 60 are switched in, the positive and negative partial currents with their arithmetic signs add to form a lower effective charge/discharge current. The current sources 56 and 62, and the current sinks 60 and 66, always provide the same capacity to supply or consume current, and thus always operate with constant individual current levels. In other words, approximately the same current always flows through the current sources 56 and 62, as well as the current sinks 60 and 66. As a desirable consequence, their operating points and dynamic properties thus change only negligibly. The magnitude of the current of the first current source 56 and the first current sink 60, and thus the magnitude of the difference of the currents in the high-current and low-current cases, must be sufficiently large to ensure good dynamic properties of the sources and thus a sharp pulse shape in every operating state.

The current control elements 76, 78 are preferably controlled synchronously, and thus in parallel, by a control signal I_CP_SW which is output by the control unit 24. The current control elements 76, 78 and the switches 68, 70, 72, 74 can be implemented by transistors, for example.

In the case of an asymmetry in the “UP” and “DOWN” pulses on settling, which is to say if their effects do not cancel one another out, a current level of 5 mA in the high-current case, and a current level of 0.5 mA in the low-current case, are thus available for charge transfer in the capacitors 25, 26 of the loop filter 22.

Within the scope of the invention, the current control elements 76, 78 are operated such that in the steady state with closed (conducting) current control elements 76, 78 only low currents arise in total at the nodes 58 and 64, whereas operation during switchover takes place with open current control elements, which increases the sum of the currents at the nodes 58 and 64.

FIG. 5a shows a plot over time of a control signal I_CP_SW that controls the charge pump 20 and that is output by the control unit 24 in FIG. 1, before, during and after the change of frequency of the phase locked loop 10. In a first time period 82, the signal level is low, which corresponds to closed current control elements 74, 76 and a first steady state before a frequency change.

FIG. 5b shows a comparatively low frequency of the phase locked loop 10 in this first time period 82. A charge transfer of the loop filter capacitors 25, 26 then takes place after the change of the division factor N in block 14 of FIG. 1 when a new frequency is programmed. In order to reach this frequency quickly and quickly transfer charge in the loop filter, the charge currents of the charge pump are raised by opening the current control elements 74, 76 via a high I_CP_SW level and an accompanying increase in the charge/discharge current levels in the second time period 84.

The associated plot of the frequency in FIG. 5b shows a time-limited settling process with a corresponding increase in the frequency bandwidth (projection of the frequency curve from the section 84 onto the ordinate). After the settling accomplished with high charge pump current levels, the level of the control signal I_CP_SW is again lowered in the third time period 86, which again closes the current control elements 76 and 78, and thus reduces the current level at the nodes 58 and 64.

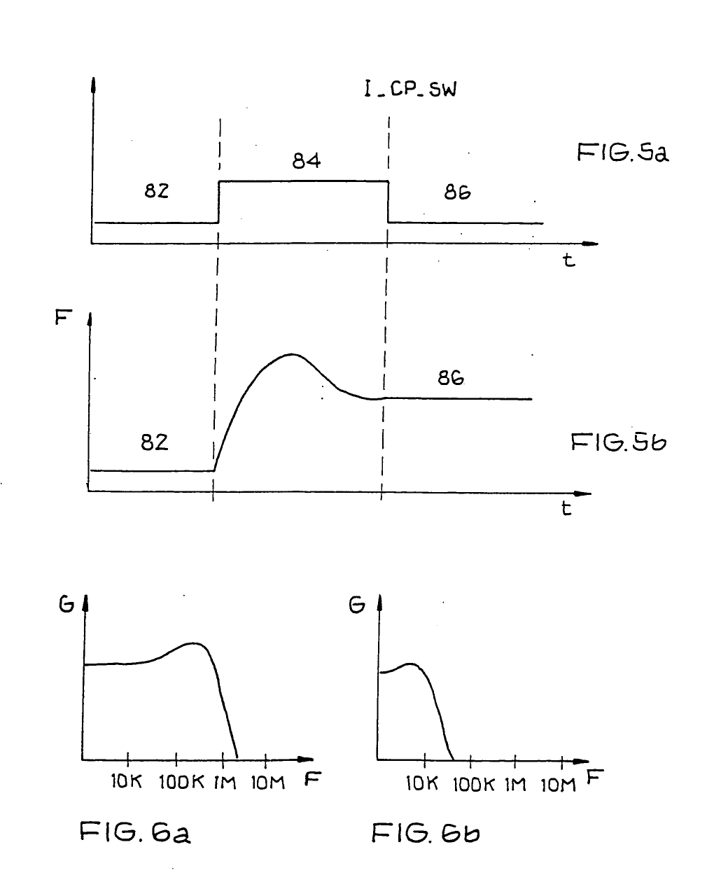

FIG. 6 qualitatively shows the loop gain G of the phase locked loop over frequency plotted logarithmically in the settling period 84 (FIG. 6a) and in the steady states in the periods 82, 84 (FIG. 6b). The comparatively wide curve in FIG. 6a is helpful for rapid settling at switchover of the frequency, and the comparatively narrow curve in FIG. 6b represents the good noise characteristics of the system in the steady state, since the damping of the filter suppresses noise components outside the frequency range 28 covered by the curve.

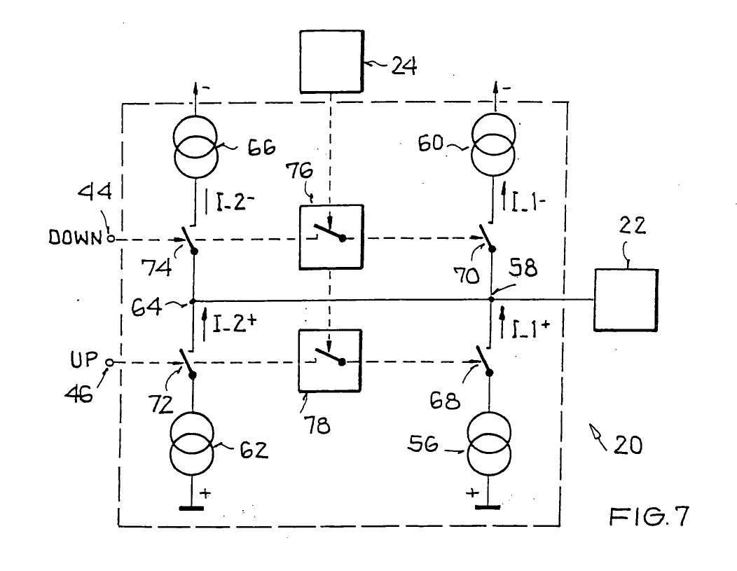

FIG. 7 shows a second example embodiment of an inventive charge pump 20 that corresponds to the aforementioned parallel connection of two charge pumps. Within the framework of this embodiment, the current sources 56 and 62 and the current sinks 60 and 66 are dimensioned, for example, such that the first current source 56 supplies a current level of 4.5 mA, the first current sink 60 draws a current level of 4.5 mA, the second current source 62 supplies a current level of 0.5 mA, and the second current sink draws a current level of 0.5 mA. Beyond these specific example values, the relationships explained above in connection with the cross-connection embodiment apply analogously to the dimensioning of the specified current levels. Within the framework of the example embodiment shown in FIG. 7, the low-current case is implemented by switching out the first current source 56 and the first current sink 60 so that the charge pump outputs to the loop filter 22 charge current pulses and discharge current pulses with values in each case of 0.5 mA, for example. The high-current case is correspondingly implemented by switching in the first current source 56 and the first current sink 60 so that in the high-current case the charge pump 20 outputs charge current pulses and discharge current pulses with values in each case of 4.5+0.5=5 mA.

Accordingly, each current source and current sink pair can be adapted to the relevant dynamic characteristics, and for every current case sharp pulses can be obtained at the output of the charge pump 20 from FIG. 1.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

1. A charge pump of a phase locked loop, the charge pump comprising:
a first current source that supplies a first additive partial current to a first node;
a first current sink that draws a first subtractive partial current from the first node;
a second current source that supplies a second additive partial current to a second node;
a second current sink that draws a second subtractive partial current from the second node; and
a first current control element and a second current control element, the first current control element controlling a combined action of a first subset of the first and second current sources and the first and second current sinks, the second current control element controlling a combined action of a second subset of the first and second current sources and the first and second current sinks that is complementary to the first subset, such that lower effective current levels of the charge pump are produced in a first control state than in a second control state.

2. The charge pump according to claim 1, wherein the first subset includes the first current source and the second current source, wherein the complementary second subset includes the first current sink and the second current sink, wherein an effective charge current results from the sum of contributions from the first current source and the second current source, and wherein an effective discharge current results from the sum of contributions from the first current sink and the second current sink.

3. The charge pump according to claim 2, wherein a contribution of the first current source and a contribution of the first current sink to the effective current level of the charge pump in the first control state, is at least smaller than in the second control state.

4. The charge pump according to claim 1, wherein the first subset includes the second current source and the first current sink, and the complementary second subset includes the second current sink and the first current source.

5. The charge pump according to claim 1, wherein the first current control element influences the first additive partial current that the first current source supplies to the first node, and wherein the second current control element influences the first subtractive partial current that the second current sink draws from the first node.

6. The charge pump according to claim 6, wherein the first current control element digitally switches the first additive partial current on or off, and wherein the second current control element digitally switches the first subtractive partial current on or off.

7. The charge pump according to claim 1, wherein the first current source supplies a current level such as is drawn by the first current sink, and wherein the second current sink draws a current level such as is supplied by the second current source.

8. The charge pump according to claim 1, wherein a current level supplied by the first current source is smaller than a current level drawn by the second current sink, or vice versa.

9. The charge pump according to claim 1, further comprising a control unit that actuates the first current control element and the second current control element in parallel.

10. A method for controlling a charge pump of a phase locked loop, the method comprising the steps of:
supplying a first additive partial current from a first current source to a first node;
drawing a first subtractive partial current from the first node by a first current sink;
supplying a second additive partial current from a second current source to a second node; and
drawing a second subtractive partial current from the second node by a second current sink,
wherein a combined action of a first subset of the first and second current sources and the first and second current sinks is controlled by a first current control element, and
wherein a combined action of a second subset of the first and second current sources and the first and second current sinks, which is complementary to the first subset, is controlled by a second current control element such that lower effective current levels of the charge pump result in a first control state than in a second control state.

11. The method according to claim 10, wherein a sum of the second additive partial current of the second current source and the first subtractive partial current of the first current sink provide a charge current for a loop filter of the phase locked loop, wherein a sum of the second subtractive partial current of the second current sink and the first additive partial current of the first current source provide a discharge current for the loop filter, wherein the discharge current is varied by the first current control element that controls the sum of the second subtractive partial current and the first additive partial current, and wherein the charge current is varied by the second current control element that controls the sum of the second subtractive partial current and the first additive partial current.

12. The method according to claim 11, wherein the sum of the currents is increased for a settling process at a changed frequency of the phase locked loop and is decreased in a stationary state of the phase locked loop.

13. The method according to claim 11, wherein the first current control element and the second current control element are actuated in parallel.

14. The method according to claim 11, wherein the first subtractive partial current is digitally switched on or off, and wherein the second additive partial current is digitally switched on or off.
